(19) United States
(12) Patent Application Publication
(10) Pub. No.: US 2009/0185408 A1
(43) Pub. Date: Jul. 23, 2009

(54) MEMORY DEVICE, MEMORY SYSTEM AND METHOD FOR DESIGN OF MEMORY DEVICE

(75) Inventor: Tsutomu TAKENAKA, Musashino-shi (JP)

Correspondence Address: SUGHRUE MION, PLLC, 2100 PENNSYLVANIA AVENUE, N.W., SUITE 800, WASHINGTON, DC, 20037, US

(73) Assignee: Yokogawa Electric Corporation, Tokyo (JP)

(21) Appl. No.: 12/356,976

(22) Filed: Jan. 21, 2009

(30) Foreign Application Priority Data
Jan. 21, 2008 (JP) 2008-010396

(51) Int. Cl. G11C 5/06; G06F 13/00; G06F 12/00; G06F 1/04

(52) U.S. Cl. 365/63; 713/600; 711/154; 716/1; 711/E12.001

(57) ABSTRACT

A memory device may include, but is not limited to, at least one memory module, and a plurality of lumped constant circuit elements. The at least one memory module is electrically coupled to a transmission system that has a characteristic impedance. The plurality of lumped constant circuit elements with an inductance is placed on the transmission system symmetrically with reference to the at least one memory module. The plurality of lumped constant circuit elements in cooperation with the at least one memory module performs as at least one low-pass filter.

### BACKGROUND OF THE INVENTION

1. Field of the Invention

The present invention generally relates to a memory device, a memory system and a method of design for a memory device.

Priority is claimed on Japanese Patent Application No. 2008-10396, filed Jan. 21, 2008, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more filly the state of the art to which the present invention pertains.

In general, a memory system may include, but not limited to, a memory device including a memory, and a memory controller that controls the memory device. In general, the memory system can be used for a wide variety of apparatus such as computers and semiconductor testers. The memory system may, in general, include a memory connector that is connected to the memory controller primarily for flexibly responding to the change of memory capacity. In general, the memory device as a memory module can be removably connected to the memory connector.

Japanese Unexamined Patent Application, First Publication No. 2001-256175 discloses a memory system that includes a memory controller and a transmission line having a first end which is connected to the memory controller. The memory system further includes a memory module as a memory device having a plurality of memory chips. The memory chip has clock terminals and data terminals which are connected through wirings to the transmission line. The transmission line has a second end connected to a terminal resistance that absorbs reflection of a signal. This circuit configuration suppresses the reflection of signal, thereby suppressing the deterioration of the waveform of the signal. The suppression to the deterioration of the waveform of the signal can improve the reliability of the signal transmission, thereby increasing the stability of memory operation and suppressing the increase of access time.

Norihiko NAONO et al. “Detailed Description of Design for High Speed Digital System” published by Nikkei BP discloses a transmission line that has a narrower portion that is connected to a load capacitance in order to provide high impedance, so as to suppress the deterioration of the waveform of a high frequency signal being transmitted on the transmission line.

Japanese Unexamined Patent Application, First Publication No. 2005-150644 discloses a transmission line that includes a plurality of segments and memory connected to the transmission line, so that the reflection of a signal is caused at the boundary between two adjacent segments, thereby causing reflected waveforms. The reflected waveform is superimposed with the non-reflected signal or other reflected signal, thereby reducing the distortion of the waveform of the signal. Optimization algorithm such as genetic algorithm is used to design characteristic impedance of each segment so as to cause a reflected waveform at the boundary between two adjacent segments, so that the reflected waveform reduces the strain of the waveform of a signal that is propagating on the transmission line.

In recent years, the requirement for high speed performance of the memory has been on the increase. In general, Double-Data-Rate2 Synchronous Dynamic Random Access Memory (DDR2 SDRAM) has been used as a main memory of a variety of computer, for example, personal computers. The next generation main memory will be a Double-Data-Rate3 Synchronous Dynamic Random Access Memory (DDR3S DRAM). The next-next generation main memory will be a Double-Data-Rate4 Synchronous Dynamic Random Access Memory (DDR4S DRAM). The theoretical data transfer rate of the DDR3S DRAM is higher by two times than that of the DDR2S DRAM.

The memory system disclosed in Japanese Unexamined Patent Application, First Publication No. 2001-256175 will be described. Increase of the data transfer rate of the memory system increases the frequency component included in a signal that is propagating on a transmission line, thereby generating a reflected wave from each memory chip that is connected to the transmission line. The reflected wave from each memory chip is superimposed on the original signal on the transmission line. Superimposition of the reflected wave on the original signal results in deterioration of the signal, thereby causing disturbance to data writing and reading.

FIG. 10A is a diagram illustrating variation of simulated eye aperture ratio over time in writing operation of a memory chip of the memory system in the related art. FIG. 10B is a diagram illustrating a variation of simulated eye aperture ratio over time in reading operation of the memory chip of the memory system in the related art. This memory system in the related art is disclosed in Japanese Unexamined Patent Application, First Publication No. 2001-256175. The simulation was made under the condition that four memory chips are connected to a transmission line, and a data transfer rate is 666 Mbps at a clock frequency of 333 MHz.

In FIG. 10A, P101 represents variation of a simulated eye aperture ratio over time for writing data in a memory chip that is closest to a memory controller. P102 represents variation of another simulated eye aperture ratio over time for writing data in another memory chip that is second closest to the memory controller. P103 represents variation of still another simulated eye aperture ratio over time for writing data in still another memory chip that is third closest to the memory controller. P104 represents variation of yet another simulated eye aperture ratio over time for writing data in yet another memory chip that is most distant from the memory controller.

In FIG. 10B, P201 represents variation of a simulated eye aperture ratio over time for reading data out of the memory chip that is closest to the memory controller. P204 represents variation of another simulated eye aperture ratio over time for reading data out of the memory chip that is most distant from the memory controller.

FIGS. 10A and 10B show deterioration of the simulated eye aperture ratio for writing and reading data to every memory chip.

Application of the technique disclosed in “Detailed Description of Design for High Speed Digital System” to the other technique disclosed in Japanese Unexamined Patent Application, First Publication No. 2001-256175 is not effective to prevent the deterioration of the signal waveform due to the following reasons. The technique disclosed in “Detailed Description of Design for High Speed Digital System” is related to a system of local impedance-matching. Application of this local impedance-matching system is difficult to remove the reflection completely. Rather some impedance-mismatching points may cause reflected waves to be superimposed on each other, thereby causing large deterioration of the signal.

The technique disclosed in Japanese Unexamined Patent Application, First Publication No. 2005-150644 needs very complicated design process using a special optimization algorithm such as genetic algorithm. For example, a special computer program and a special circuit such as Simulation Program with Integrated Circuit Emphasis (SPICE) using such the special optimization algorithm need to be used. Thus, this technique is time-consuming and costly technique.

In view of the above, it will be apparent to those skilled in the art from this disclosure that there exists a need for an improved memory device, memory system and/or method of design for a memory device. This invention addresses this need in the art as well as other needs, which will become apparent to those skilled in the art from this disclosure.

### SUMMARY OF THE INVENTION

Accordingly, it is a primary object of the present invention to provide a memory device.

It is another object of the present invention to provide a memory device that can prevent signal deterioration due to signal reflection even at a high data transfer rate, without using a very complicated design method.

It is a further object of the present invention to provide a memory system.

It is a still further object of the present invention to provide a memory system that can prevent signal deterioration due to signal reflection even at a high data transfer rate, without using a very complicated design method.

It is yet a further object of the present invention to provide a method of design for a memory device.

It is an additional object of the present invention to provide a method of design for a memory device that can prevent signal deterioration due to signal reflection even at a high data transfer rate, without using a very complicated design method.

In accordance with a first aspect of the present invention, a memory device may include, but is not limited to, at least one memory module, and a plurality of lumped constant circuit elements. The at least one memory module is electrically coupled to a transmission system that has a characteristic impedance. The plurality of lumped constant circuit elements with an inductance is placed on the transmission system symmetrically with reference to the at least one memory module. The plurality of lumped constant circuit elements in cooperation with the at least one memory module performs as at least one low-pass filter. The at least one low-pass filter is matched to the characteristic impedance.

In some cases, the at least one low-pass filter may have a cut-off frequency that is higher than a clock frequency of a clock signal that is used to transmit a signal on the transmission system.

In some cases, each of the plurality of lumped constant circuit elements may include, but is not limited to, a chip inductor and/or a line inductor that extends from the transmission system, wherein the line inductor may include, but is not limited to, a non-parallel portion that is not parallel to the transmission system.

In some cases, the at least one memory module may include, but is not limited to, a plurality of memory modules electrically coupled to a plurality of transmission lines included in the transmission system. The plurality of lumped constant circuit elements in cooperation with the plurality of memory modules may perform as the third-order or fifth-order low-pass filter.

In accordance with a second aspect of the present invention, a memory system may include, is not limited to, a transmission system that includes a plurality of transmission lines that each have a characteristic impedance, a plurality of memory modules, a plurality of lumped constant circuit elements, and a memory controller. The plurality of memory modules is electrically coupled to the transmission system. The plurality of lumped constant circuit elements with an inductance is placed on the transmission system symmetrically with reference to the plurality of memory modules. The plurality of lumped constant circuit elements in cooperation with the the plurality of memory modules may perform as at least one low-pass filter. The memory controller is electrically coupled to the transmission system. The memory controller may control operations of writing information into the plurality of memory modules and reading information out of the plurality of memory modules. The at least one low-pass filter is matched to the characteristic impedance.

In some cases, the memory system may further include at least one additional lumped constant circuit element with an inductance. The at least one additional lumped constant circuit element is placed on the transmission system. The at least one additional lumped constant circuit element in cooperation with the memory controller may perform as an additional low-pass filter.

In some cases, the at least one low-pass filter has a cut-off frequency that is higher than a clock frequency of a clock signal that is used to transmit a signal on the transmission system.

In some cases, each of the plurality of lumped constant circuit elements comprises a chip inductor and/or a line inductor that extends from the transmission system. The line inductor may include, but is not limited to, a non-parallel portion that is not parallel to the transmission system.

In some cases, the at least one low-pass filter may perform as the third-order or fifth-order low-pass filter.

In accordance with a third aspect of the present invention, a method of design for a memory device may include, but is not limited to, the following processes. A plurality of lumped constant circuit elements with an inductance is placed on a transmission system that has a characteristic impedance that is electrically coupled to at least one memory module. The plurality of lumped constant circuit elements is symmetrical with reference to the at least one memory module. The inductance of the plurality of lumped constant circuit elements is decided, so that the plurality of lumped constant circuit elements in cooperation with the at least one memory module performs as at least one low-pass filter. The at least one low-pass filter is matched to the characteristic impedance.

In some cases, the at least one low-pass filter may have a cut-off frequency that is higher than a clock frequency of a clock signal that is used to transmit a signal on the transmission system.

As described above, the at least one low-pass filter is matched to the characteristic impedance. As a result, no unnecessary reflection is caused throughout the transmission system, thereby preventing deterioration of a signal due to signal reflection. This allows high speed operations of writing and reading data into the memory module. The design for the memory device is basically similar to the design for the low-pass filter. The design for the memory device can be made without using any complicated design processes.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a diagram illustrating the configuration of a memory device and a memory system in accordance with a first preferred embodiment of the present invention;

FIG. 2A is a diagram illustrating the equivalent circuit of the memory system of FIG. 1, wherein data is written into memory modules;

FIG. 2B is a diagram illustrating the equivalent circuit of the memory system of FIG. 1, wherein data is read out of memory modules;

FIG. 3A is a diagram illustrating variation of simulated eye aperture ratio over time in writing operation of memory modules of the memory system shown in FIGS. 1, 2A and 2B;

FIG. 3B is a diagram illustrating a variation of simulated eye aperture ratio over time in reading operation of memory modules of the memory system shown in FIGS. 1, 2A and 2B;

FIG. 4A is a diagram illustrating variation of simulated eye aperture ratio over time in writing operation of memory modules of the memory system shown in FIGS. 1, 2A and 2B in accordance with a third embodiment of the present invention;

FIG. 4B is a diagram illustrating a variation of simulated eye aperture ratio over time in reading operation of memory modules of the memory system shown in FIGS. 1, 2A and 2B in accordance with a third embodiment of the present invention;

FIG. 5 is a diagram illustrating an equivalent circuit of a memory system in accordance with a third embodiment of the present invention;

FIG. 6A is a diagram illustrating variation of simulated eye aperture ratio over time in writing operation of memory modules of the memory system shown in FIG. 5;

FIG. 6B is a diagram illustrating a variation of simulated eye aperture ratio over time in reading operation of memory modules of the memory system shown in FIG. 5;

FIG. 7 is a diagram illustrating an equivalent circuit of a memory system in accordance with a fourth embodiment of the present invention;

FIG. 8A is a diagram illustrating variation of simulated eye aperture ratio over time in writing operation of memory modules of memory system shown in FIG. 7;

FIG. 8B is a diagram illustrating a variation of simulated eye aperture ratio over time in reading operation of memory modules of the memory system shown in FIG. 7;

FIG. 9 is a diagram illustrating an equivalent circuit of a memory system in accordance with a fifth embodiment of the present invention;

FIG. 10A is a diagram illustrating variation of simulated eye aperture ratio over time in writing operation of a memory chip of the memory system in the related art; and

FIG. 10B is a diagram illustrating a variation of simulated eye aperture ratio over time in reading operation of the memory chip of the memory system in the related art.

### DETAILED DESCRIPTION OF THE INVENTION

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

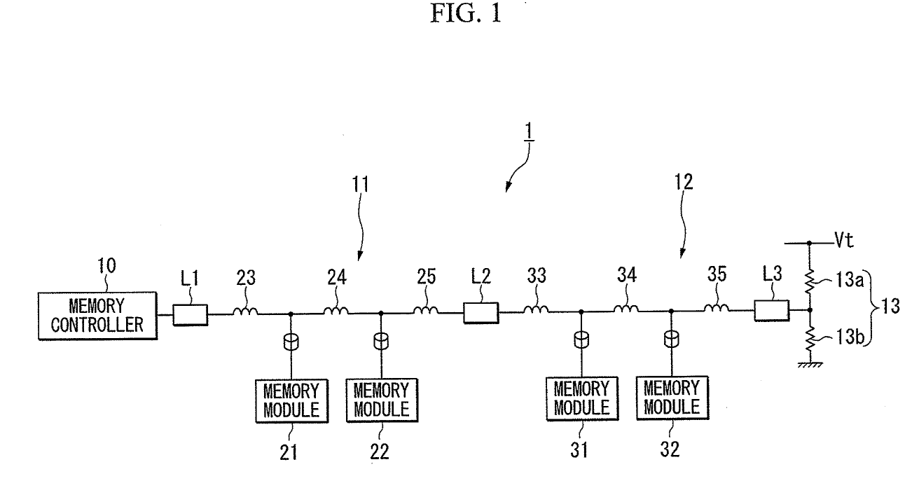

FIG. 1 is a diagram illustrating the configuration of a memory device and a memory system in accordance with a first preferred embodiment of the present invention. A memory system 1 may include, but is not limited to, a memory controller 10, a transmission system that includes transmission lines L1, L2 and L3, memory devices 11 and 12, and a terminal resistance 13. The memory controller 10 and the memory device 11 are connected to each other through the transmission line L1. The memory devices 11 and 12 are also connected to each other through the transmission line L2. The memory device 12 and the terminal resistance 13 are connected to each other through the transmission line L3. FIG. 1 simply represents a bundle of transmission lines by a single line that includes the transmission lines L1, L2 and L3.

The memory controller 10 controls the operation of writing data into the memory devices 11 and 12 and the operation of reading data out of the memory devices 11 and 12. Each of the transmission lines L1, L2 and L3 has characteristic impedance Z₀, for example, but not limited to, 50Ω. The transmission lines L1, L2 and L3 constitutes a single transmission system that provides connection between the memory controller 10 and the memory devices 11 and 12. The transmission line L1 connects the memory controller 10 and the memory device 11. The transmission line L2 connects the memory devices 11 and 12. The transmission line L3 connects the memory device 12 and the terminal resistance 13.

The memory device 11 may include, but is not limited to, memory modules 21 and 22 and a plurality of lumped constant circuit elements with inductance. The memory modules 21 and 22 perform as memories. The plurality of lumped constant circuit elements are placed symmetrically with reference to the memory modules 21 and 22. In some cases, the plurality of lumped constant circuit elements can be realized by, but not limited to, chip inductors 23, 24, and 25. The memory modules 21 and 22 can be realized by, but not limited to, modules that accord to the regulation “Dual InLine Memory Module” (DIMM). The module may include, but is not limited to, memory chips that are not illustrated. In some cases, the memory chips may be realized by, but not limited to, memory chips according to the regulation “DDRSDRAM” or “DDR2 SDRAM”. Each of the memory modules 21 and 22 may further include a terminal that is connected to the memory chip. The terminal is also connected to the transmission line that includes the transmission lines L1, L2 and L3. Thus, each of the memory modules 21 and 22 is connected through the terminal to the transmission line that includes the transmission lines L1, L2 and L3 The chip inductors 23, 24, and 25 are disposed on the transmission line that includes the transmission lines L1, L2 and L3. The chip inductors 23, 24, and 25 are placed symmetrically with reference to the memory modules 21 and 22. The chip inductors 23, 24, and 25 are disposed between the transmission lines L1 and L2. The memory module 21 is disposed between the chip inductors 23 and 24, The memory module 22 is disposed between the chip inductors 24 and 25. The chip inductor 23 is disposed between the transmission line L1 and the chip inductor 24. The chip inductor 24 is disposed between the chip inductors 23 and 25. The chip inductor 25 is disposed between the chip inductor 24 and the transmission line L2. The chip inductors 23, 24, and 25 in cooperation with the memory modules 21 and 22 perform as low-pass filter.

The memory device 12 may include, but is not limited to, memory modules 31 and 32 and chip inductors 33, 34, and 35. The memory modules 31 and 32 perform as memories. The chip inductors 33, 34, and 35 can be realized by, but not limited to, lumped constant circuit elements. The memory modules 31 and 32 can be realized by, but not limited to, modules that accord to the regulation “Dual InLine Memory Module” (DIMM). The module may include, but is not limited to, memory chips that are not illustrated. In some cases, the memory chips may be realized by, but not limited to, memory chips according to the regulation “DDRSDRAM” or “DDR2 SDRAM”. Each of the memory modules 31 and 32 may further include a terminal that is connected to the memory chip. The terminal is also connected to the transmission line that includes the transmission lines L1, L2 and L3. Thus, each of the memory modules 31 and 32 is connected through the terminal to the transmission line that includes the transmission lines L1, L2 and L3.

The chip inductors 33, 34, and 35 are disposed on the transmission line that includes the transmission lines L1, L2 and L3. The chip inductors 33, 34, and 35 are disposed symmetrically with reference to the memory modules 31 and 32. The chip inductors 33, 34, and 35 are disposed between the transmission lines L2 and L3. The memory module 31 is disposed between the chip inductors 33 and 34. The memory module 32 is disposed between the chip inductors 34 and 35. The chip inductor 33 is disposed between the transmission line L2 and the chip inductor 34. The chip inductor 34 is disposed between the chip inductors 33 and 35. The chip inductor 35 is disposed between the chip inductor 34 and the transmission line L3. The chip inductors 33, 34, and 35 in cooperation with the memory modules 31 and 32 perform as low-pass filter.

The terminal resistance 13 is connected to the transmission line L3. In some cases, the terminal resistance 13 can be realized by, but not limited to, a series connection of resistances 13a and 13b between a power line and the ground. The transmission line L3 is connected to the connecting point between the resistances 13a and 13b. The resistances 13a and 13b can form Thevenin termination.

As described above, the memory system may include the memory controller 10, the terminal resistance 13, the transmission line between the memory controller 10, the terminal resistance 13, and the memory modules 21, 22, 31, and 32 connected to the transmission line. The transmission line may include the transmission lines L1, L2, and L3 and the chip inductors 23, 24, 25, 33, 34, and 35.

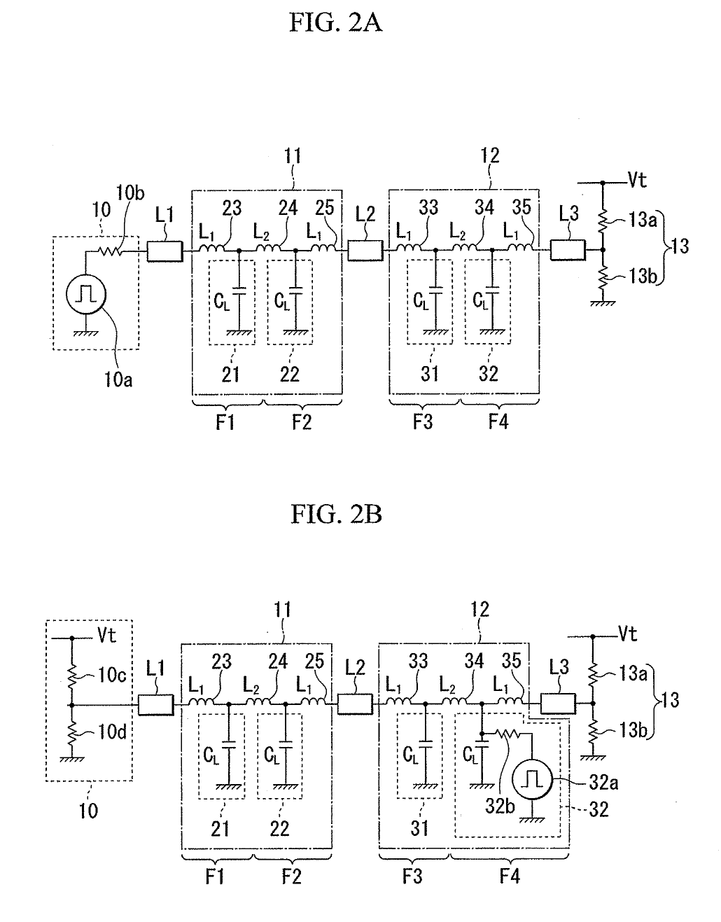

FIG. 2A is a diagram illustrating the equivalent circuit of the memory system 1 of FIG. 1, wherein data is written into the memory modules 21, 22, 31, and 32. FIG. 2B is a diagram illustrating the equivalent circuit of the memory system 1 of FIG. 1, wherein data is read out of the memory modules 21, 22, 31, and 32.

As shown in FIG. 2A, when data is written into the memory modules 21, 22, 31, and 32, the memory controller 10 is equivalent to a circuit that includes a signal source 10a, and an internal resistance 10b. The memory modules 21, 22, 31, and 32 are equivalent to capacitors C_{L}.

As shown in FIG. 2B, when data is read out of the memory modules 21, 22, 31, and 32, the memory controller 10 is equivalent to a Thevenin termination resistance that includes a series connection of resistances 10c and 10d. No reading operation is made for the memory modules 21, 22 and 31, while data is read out of the memory module 32. The memory modules 21, 22 and 31 are equivalent to capacitors C_{L}. The memory module 32 is equivalent to a circuit that includes a signal source 32a, a matched resistance 32b and a capacitor C_{L}. The signal source 32a and the matched resistance 32b are connected in series between the transmission line and the ground. The capacitor C_{L} is also connected in series between the transmission line and the ground. The capacitor C_{L} and the series connection of the signal source 32a and the matched resistance 32b are connected to the transmission line in parallel to each other.

The memory system includes the memory controller 10, the memory devices 11 and 12, the terminal resistance 13, the transmission lines L1, L2 and L3. The transmission line L1 is disposed between the memory controller 10 and the memory device 11. The transmission line L2 is disposed between the memory devices 11 and 12. The transmission line L3 is disposed between the memory device 12 and the terminal resistance 13. The memory device 11 includes the memory modules 21 and 22 and the chip inductors 23, 24, and 25. The memory device 12 includes the memory modules 31 and 32 and the chip inductors 33, 34, and 35.

A method for design of the memory device as described above will be described. As described above, the memory device 11 includes the memory modules 21 and 22 and the chip inductors 23, 24 and 25. The memory device 12 includes the memory modules 31 and 32 and the chip inductors 33, 34, and 35. The design will be made, provided that the memory devices 11 and 12 are regarded as a series connection of third-order T-low-pass filters that are impedance-matched to the characteristic impedance Z₀. In some cases, the method for design of the memory device may be as follows.

In the first step, the transmission line is prepared which includes the transmission lines L1, L2 and L3, wherein the transmission line is connected with the memory modules 21 and 22 that are equivalent to the capacitors C_{L}. The chip inductors 23, 24 and 25 are placed on the transmission line symmetrically with reference to the memory modules 21 and 22. The chip inductor 23 is placed between the transmission line L1 and the connecting point of the transmission line to the memory module 21. The chip inductor 24 is placed between the connecting point of the transmission line to the memory module 21 and the other connecting point of the transmission line to the memory module 22. The chip inductor 25 is placed between the transmission line L2 and the other connecting point of the transmission line to the memory module 22. Each of the chip inductors 23 and 25 has an inductance L₁. The chip inductor 24 has an inductance L₂.

The memory device 11 includes the memory modules 21 and 22 and the chip inductors 23, 24, and 25. The memory device 11 is regarded as a circuit of a series connection of first and second low-pass filters F1 and F2. The first low-pass filter F1 is realized by the third-order T-low-pass filter that includes the memory module 21 and the chip inductors 23 and 24. The second low-pass filter F2 is realized by the third-order T-low-pass filter that includes the memory module 22 and the chip inductors 24 and 25. The inductances L₁ and L₂ are determined provided that the memory device 11 is regarded as the above-described circuit of the series connection of the first and second low-pass filters F1 and F2, and each of the first and second low-pass filters F1 and F2 may be either a Chebyshev filter or a Butterworth filter.

The capacitance C_{L} is determined in accordance with the specification of the memory chips of the memory modules 21 and 22. If the memory modules 21 and 22 include memory chips that accord to the regulation “DDR2 SDRAM”, the capacitors that are equivalent to the memory modules 21 and 22 have a capacitance C_{L} of about 3 [pF]. The cutoff frequency of the first and second low-pass filters is set higher than the clock frequency of a clock signal that is used to transmit a signal through the transmission line. The resistance value R of the resistances 13a and 13b is set to be higher by two times than the characteristic impedance Z₀ of the transmission lines L1, L2, and L3. Namely, the resistance value R of the resistances 13a and 13b is set to be 2×Z₀.

The design method for the memory device 12 is similar to the above-described design method for the memory device 12. The chip inductors 33, 34 and 35 are placed on the transmission line symmetrically with reference to the memory modules 31 and 32. The chip inductor 33 is placed between the transmission line L2 and the connecting point of the transmission line to the memory module 31. The chip inductor 34 is placed between the connecting point of the transmission line to the memory module 31 and the other connecting point of the transmission line to the memory module 32. The chip inductor 35 is placed between the transmission line L3 and the other connecting point of the transmission line to the memory module 32. Each of the chip inductors 33 and 35 has an inductance L₁. The chip inductor 34 has an inductance L₂.

The memory device 12 includes the memory modules 31 and 32 and the chip inductors 33, 34, and 35. The memory device 12 is regarded as a circuit of a series connection of third and fourth low-pass filters F3 and F4. The third low-pass filter F3 is realized by the third-order T-low-pass filter that includes the memory module 31 and the chip inductors 33 and 34. The fourth low-pass filter F4 is realized by the third-order T-low-pass filter that includes the memory module 32 and the chip inductors 34 and 35. The inductances L₁ and L₂ are determined provided that the memory device 12 is regarded as the above-described circuit of the series connection of the third and fourth low-pass filters F3 and F4, and each of the third and fourth low-pass filters F3 and F4 may be either a Chebyshev filter or a Butterworth filter.

The capacitance C_{L} is determined in accordance with the specification of the memory chips of the memory modules 31 and 32. If the memory modules 31 and 32 include memory chips that accord to the regulation “DDR2 SDRAM”, the capacitors that are equivalent to the memory modules 31 and 32 have a capacitance C_{L} of about 3 [pF]. The cutoff frequency of the third and fourth low-pass filters is set higher than the clock frequency of a clock signal that is used to transmit a signal through the transmission line. The resistance value R of the resistances 13a and 13b is set to be higher by two times than the characteristic impedance Z₀ of the transmission lines L1, L2, and L3. Namely, the resistance value R of the resistances 13a and 13b is set to be 2×Z₀.

If the characteristic impedance for the transmission lines L1, L2 and L3 is 50 [Ω], the resistance value R of the terminal resistances 13a and 13b is 100 [Ω], and if the capacitance C_{L} of the capacitors that are equivalent to the memory modules 21 and 22 is 3.0 [pF] and the above-described cut-off frequency is 2.1 [GHz] and the low-pass filters are Butterworth filters, then the inductance L₁ of the chip inductors 23, 25, 33 and 35 is 3.8 [nH] and the inductance L₂ of the chip inductors 24 and 34 is 7.6 [nH].

Adjustment or correction to the inductances of the chip inductors 23, 24, 25, 33, 34, and 35 can be made. The adjustment or correction to the inductances of the chip inductors 23, 24, 25, 33, 34, and 35 are made to countermeasure variation of the capacitors equivalent to the memory modules 21 and 22. The adjustment or correction can be made to countermeasure parasitic transistors. The adjustment or correction can be made to countermeasure differences of the specifications of the memory controller 10 and the parasitic capacitance thereof. The adjustment to the inductances of the chip inductors 23, 24, 25, 33, 34, and 35 can be made in the range of about ½ times to about 3 times of the values obtained in accordance with the above-described design method. The correction to the inductances of the chip inductors 23, 24, 25, 33, 34, and 35 can be made using a circuit simulator. The adjustment or correction can be made so that the group delay is in the cut-off frequency band and in the range of about ½ times to about 2 times of the averaged value thereof.

In accordance with the above descriptions, the single chip inductor 24 is interposed between the memory modules 21 and 22, and the single chip inductor 34 is interposed between the memory modules 31 and 32. In the actual memory device 11, transmission lines having a length in the range of a few milliners to a several tends millimeters that provide characteristic impedances Z₀ can be interposed between the memory modules 21 and 22. In the actual memory device 12, transmission lines having a length in the range of a few milliners to a several tends millimeters that provide characteristic impedances Z₀ can be interposed between the memory modules 31 and 32. It is possible as a modification that a plurality of chip inductors can be disposed between the memory modules 21 and 22, and another plurality of chip inductors can be disposed between the memory modules 31 and 32 for the following reasons.

Operations of the above-described memory devices and the above-described memory system will be described as follows. Operation of writing data into the memory module 32 will be described before operation of reading out data the memory module 32 will be then described.

Data can be written into the memory module 32 as follows. As shown in FIG. 2A, a signal is output from the memory controller 10. The signal is then transmitted through the transmission line L1 to the first low-pass filter F1. The first low-pass filter F1 includes the chip inductors 23 and 24 and the memory module 21. No reflection of the signal is caused because the first low-pass filter F1 is matched to the characteristic impedance Z₀ in the cut-off frequency.

The signal is then transmitted from the first low-pass filter F1 through the second low-pass filter F2 to the transmission line L2. The second low-pass filter F2 includes the chip inductors 24 and 25 and the memory module 22. No reflection of the signal is caused because the second low-pass filter F2 is matched to the characteristic impedance Z₀ in the cut-off frequency. The signal is then transmitted from the transmission line L2 to the third low-pass filter F3. The third low-pass filter F3 includes the chip inductors 33 and 34 and the memory module 31. No reflection of the signal is caused because the third low-pass filter F3 is matched to the characteristic impedance Z₀ in the cut-off frequency. The signal is then transmitted from the third low-pass filter F3 to the fourth low-pass filter F4, where data is written into the memory module 32. The fourth low-pass filter F4 includes the chip inductors 34 and 35 and the memory module 32. No reflection of the signal is caused because the fourth low-pass filter F4 is matched to the characteristic impedance Z₀ in the cut-off frequency. The signal is then transmitted from the fourth low-pass filter F4 through the transmission line L3 to the terminal resistance 13. The signal is absorbed with the terminal resistance 13.

As shown in FIG. 2B, a signal is output from the memory module 32. The signal is then transmitted through the matched resistance 32b to the connecting point of the fourth low-pass filter F4 that is matched to the characteristic impedance Z₀. The connecting point of the fourth low-pass filter F4 is an intermediate connecting point between the chip inductors 34, and 35. The intermediate connecting point is also connected to the matched resistance 32b. The signal is transmitted without unnecessary reflection toward opposing directions, for example, toward the memory controller 10 and toward the terminal resistance 13. The signal is transmitted without unnecessary reflection from the intermediate connecting point of the fourth low-pass filter F4 through the third low-pass filter F3, the transmission line L2, the second low-pass filter F24, the first low-pass filter F1 and the transmission line L1 to the memory controller 10. The memory controller 10 can be regarded as a series connection of the resistances 10c and 10d between the power voltage and the ground. The signal reaches the memory controller 10 and is absorbed by the Thevenin terminal resistance that is formed by the series connection of the resistances 10c and 10d. The signal is also transmitted without unnecessary reflection from the intermediate connecting point of the fourth low-pass filter F4 through the transmission line L3 to the terminal resistance 13. The resistance value of the matched resistance 32b is determined to be a half value of the characteristic impedance Z₀ because the connection to the memory controller 10 and the connection to the terminal resistance 13 are parallel to each other with reference to the matched resistance 32b.

As described above, the first low-pass filter F1 includes the memory module 21 and the chip inductors 23 and 24. The second low-pass filter F2 includes the memory module 22 and the chip inductors 24 and 25. The third low-pass filter F3 includes the memory module 31 and the chip inductors 33 and 34. The fourth low-pass filter F4 includes the memory module 32 and the chip inductors 34 and 35. Each of the first, second, third and fourth low-pass filters F1, F2, F3 and F4 is matched to the characteristic impedance Z₀ of the transmission lines L1, L2, and L3 in the cut-off frequency band, thereby generating no unnecessary reflection. No unnecessary reflection is caused between the transmission lines L1 and L2 and between the transmission lines L2 and L3. As a result, no unnecessary reflection is caused throughout the transmission system, thereby preventing deterioration of the signal due to signal reflection. This allows high speed operations of writing and reading data. The design for the memory devices 11 and 12 are basically similar to the design for the low-pass filter. The design for the memory devices 11 and 12 can be made without using any complicated design processes.

As described above, the memory device 11 can be designed as being regarded as a circuit of a series connection of the first and second low-pass filters F1 and F2. The first low-pass filter F1 is the third-order T-low-pass filter that includes the memory module 21 and the chip inductors 23 and 24. The second low-pass filter F2 is the third-order T-low-pass filter that includes the memory module 22 and the chip inductors 24 and 25. The memory device 12 can also be designed as being regarded as a circuit of a series connection of the third and fourth low-pass filters F3 and F4. The third low-pass filter F3 is the third-order T-low-pass filter that includes the memory module 31 and the chip inductors 33 and 34. The fourth low-pass filter F4 is the third-order T-low-pass filter that includes the memory module 32 and the chip inductors 34 and 35.

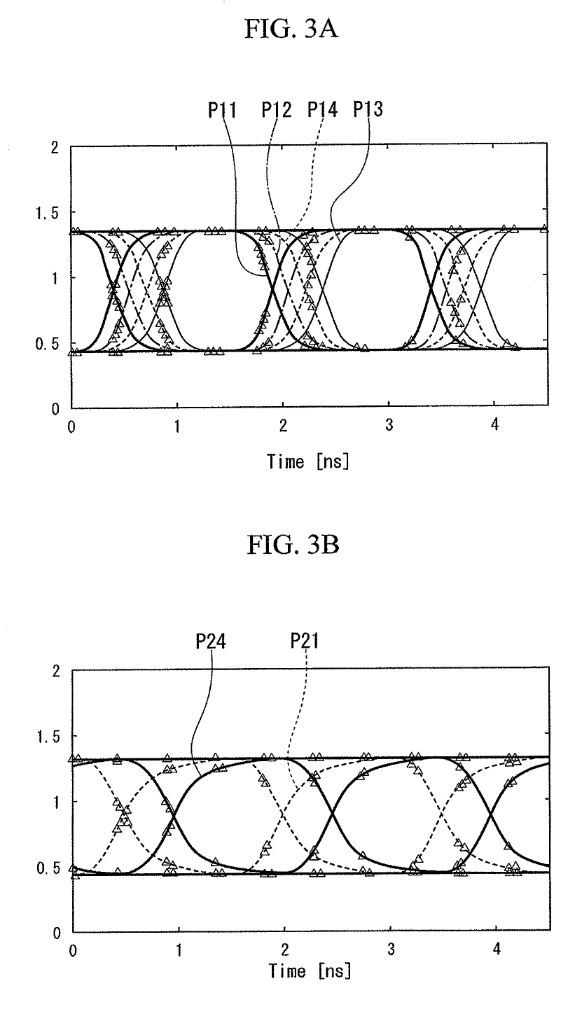

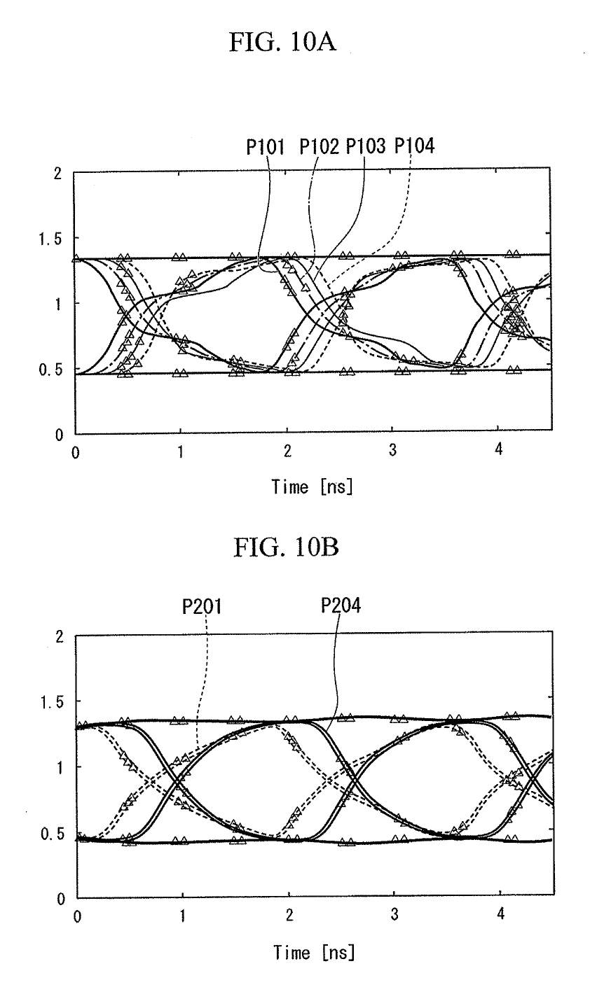

FIG. 3A is a diagram illustrating variation of simulated eye aperture ratio over time in writing operation of the memory modules 21, 22, 31, and 32 of the memory system 1 shown in FIGS. 1, 2A and 2B. FIG. 313 is a diagram illustrating a variation of simulated eye aperture ratio over time in reading operation of the memory modules 21 and 32 of the memory system 1 shown in FIGS. 1, 2A and 2B. The simulation was made under the conditions that a data transfer rate is 666 Mbps at a clock frequency of 333 MHz. These conditions are similar to those shown in FIGS. 10A and 10B.

In FIG. 3A, P11 represents variation of a simulated eye aperture ratio over time for writing data in the memory module 21. P12 represents variation of another simulated eye aperture ratio over time for writing data in the memory module 22. P13 represents variation of still another simulated eye aperture ratio over time for writing data in the memory module 31. P14 represents variation of yet another simulated eye aperture ratio over time for writing data in the memory module 32.

In FIG. 3B, P21 represents variation of a simulated eye aperture ratio over time for reading data out of the memory module 21. P24 represents variation of another simulated eye aperture ratio over time for reading data out of the memory module 32.

FIGS. 3A and 3B show that the simulated eye aperture ratios for writing and reading data to every memory chip are improved as compared to the simulated eye aperture ratios for writing or read data as shown in FIGS. 10A and 10B.

### Second Embodiment

A second embodiment of the present invention will be described. The configuration of the memory device in accordance with the second embodiment is the same as the above-described configuration of the memory device in accordance with the first embodiment. The configuration of the memory system in accordance with the second embodiment is also the same as the above-described configuration of the memory system in accordance with the first embodiment. The difference between the first and second embodiments is the different design method for the memory devices 11 and 12 included in the memory system 1.

In accordance with the first embodiment, the memory device 11 can, as described above, be designed as being regarded as a circuit of a series connection of the first and second low-pass filters F1 and F2. The first low-pass filter F1 is the third-order T-low-pass filter that includes the memory module 21 and the chip inductors 23 and 24. The second low-pass filter F2 is the third-order T-low-pass filter that includes the memory module 22 and the chip inductors 24 and 25. The memory device 12 can also be designed as being regarded as a circuit of a series connection of the third and fourth low-pass filters F3 and F4. The third low-pass filter F3 is the third-order T-low-pass filter that includes the memory module 31 and the chip inductors 33 and 34, The fourth low-pass filter F4 is the third-order T-low-pass filter that includes the memory module 32 and the chip inductors 34 and 35.

In accordance with the second embodiment, the memory device 11 can be designed as being regarded as a fifth-order T-low-pass filter that includes the memory modules 21 and 22 and the chip inductors 23, 24 and 25. The memory device 12 can be designed as being regarded as another fifth-order T-low-pass filter that includes the memory modules 31 and 32 and the chip inductors 33, 34 and 35.

If the characteristic impedance for the transmission lines L1, L2 and L3 is 50 [Ω] and if the capacitance CL of the capacitors that are equivalent to the memory modules 21 and 22 is 3.0 [pF] and the above-described cut-off frequency is 1.72 [GHz] and the fifth-order T-low-pass filters are Butterworth filters, then the inductance L₁ of the chip inductors 23, 25, 33 and 35 is 2.9 [nH] and the inductance L2 of the chip inductors 24 and 34 is 9,3 [nH].

Adjustment or correction to the inductances of the chip inductors 23, 24, 25, 33, 34, and 35 can be made. The adjustment or correction to the inductances of the chip inductors 23, 24, 25, 33, 34, and 35 are made to countermeasure variation of the capacitors CL equivalent to the memory modules 21 and 22. The adjustment or correction can be made to countermeasure parasitic transistors. The adjustment or correction can be made to countermeasure differences of the specifications of the memory controller 10 and the parasitic capacitance thereof. The adjustment to the inductances of the chip inductors 23, 24, 25, 33, 34, and 35 can be made in the range of about ½ times to about 3 times of the values obtained in accordance with the above-described design method. The correction to the inductances of the chip inductors 23, 24, 25, 33, 34, and 35 can be made using a circuit simulator. The adjustment or correction can be made so that the group delay is in the cut-off frequency band and in the range of about ½ times to about 2 times of the averaged value thereof.

The memory device 11 can be formed by the fifth-order T-low-pass filter that includes the memory modules 21 and 22 and the chip inductors 23, 24 and 25. The memory device 12 can be formed by the other fifth-order T-low-pass filter that includes the memory modules 31 and 32 and the chip inductors 33, 34 and 35. Each of the fifth-order T-low-pass filters is matched to the characteristic impedance Z₀ of the transmission lines L1, L2, and L3 in the cut-off frequency band, thereby generating no unnecessary reflection. No unnecessary reflection is caused between the transmission lines L1 and L2 and between the transmission lines L2 and L3. As a result, no unnecessary reflection is caused throughout the transmission system, thereby preventing deterioration of the signal due to signal reflection. This allows high speed operations of writing and reading data. The design for the memory devices 11 and 12 are basically similar to the design for the low-pass filter. The design for the memory devices 11 and 12 can be made without using any complicated design processes.

In the actual memory device 11, transmission lines having a length in the range of a few milliners to a several tends millimeters that provide characteristic impedances Z₀ can be interposed between the memory modules 21 and 22. In the actual memory device 12, transmission lines having a length in the range of a few milliners to a several tends millimeters that provide characteristic impedances Z₀ can be interposed between the memory modules 31 and 32. It is possible as a modification that a plurality of chip inductors can be disposed between the memory modules 21 and 22, and another plurality of chip inductors can be disposed between the memory modules 31 and 32 for the following reasons.

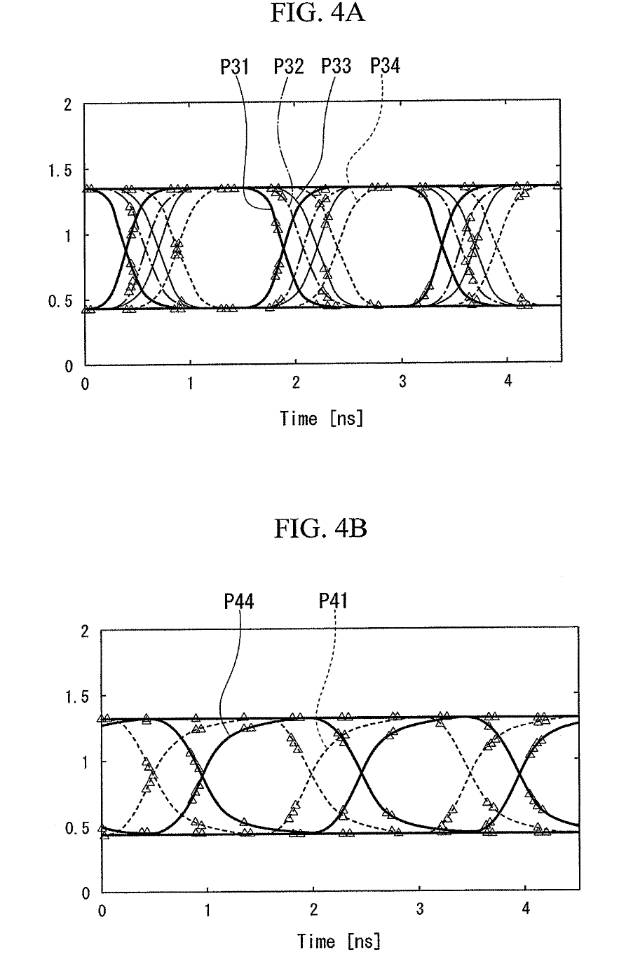

FIG. 4A is a diagram illustrating variation of simulated eye aperture ratio over time in writing operation of the memory modules 21, 22, 31, and 32 of the memory system 1 shown in FIGS. 1, 2A and 2B. FIG. 4B is a diagram illustrating a variation of simulated eye aperture ratio over time in reading operation of the memory modules 21 and 32 of the memory system 1 shown in FIGS. 1, 2A and 2B. The simulation was made under the conditions that a data transfer rate is 666 Mbps at a clock frequency of 333 MHz. These conditions are similar to those shown in FIGS. 3A and 3B.

In FIG. 4A, P31 represents variation of a simulated eye aperture ratio over time for writing data in the memory module 21. P32 represents variation of another simulated eye aperture ratio over time for writing data in the memory module 22. P33 represents variation of still another simulated eye aperture ratio over time for writing data in the memory module 31. P34 represents variation of yet another simulated eye aperture ratio over time for writing data in the memory module 32.

In FIG. 4B, P41 represents variation of a simulated eye aperture ratio over time for reading data out of the memory module 21. P44 represents variation of another simulated eye aperture ratio over time for reading data out of the memory module 32.

FIGS. 4A and 4B show that the simulated eye aperture ratios for writing and reading data to every memory chip are improved as compared to the simulated eye aperture ratios for writing and reading data as shown in FIGS. 10A and 10B.

### Third Embodiment

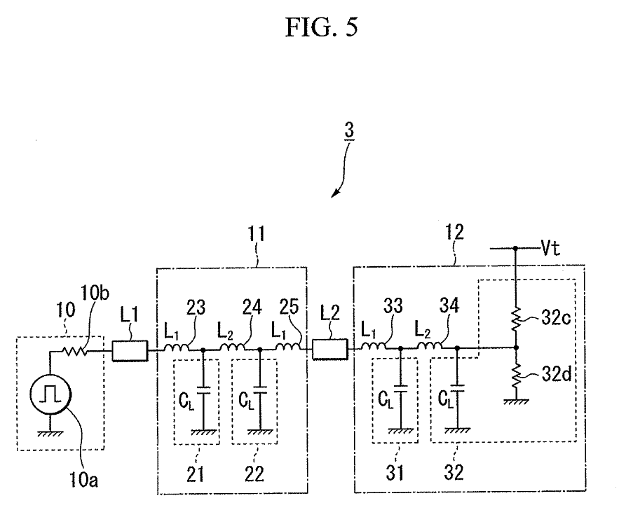

A third embodiment of the present invention will be described. FIG. 5 is a diagram illustrating an equivalent circuit of a memory system in accordance with the third embodiment of the present invention. The configuration of a memory system 3 in accordance with the third embodiment is different from the above-described configuration of the memory system in accordance with the first and second embodiments. The difference of the third embodiment from the first and second embodiments is the modified configuration of the memory module 32 that includes the capacitor C_{L} and a Thevenin terminal resistance. The Thevenin terminal resistance includes a series connection of resistances 32c and 32d between the power voltage and the ground. The connecting point between the chip inductor 34 and the capacitor C_{L} is terminated by the Thevenin terminal resistance that includes the series connection of the resistances 32c and 32d. The chip inductor 35, the transmission line L3 and the terminal resistance 13 are absent in the memory system 3 in accordance with the third embodiment, while these elements are present in the above-described memory system 1 in accordance with the first and second embodiments.

The DDR2 SDRAM and the like includes the terminal resistance in its inside, for example, On DieTermination (ODT). The terminal resistance such as the ODT can be used to terminate the connecting point between the chip inductor 34 and the memory module 32. The memory module 32 can be configured to include the Thevenin terminal resistance of the series connection of the resistances 32c and 32d so that the memory system 3 is free of the transmission line L3 and the terminal resistance 13. This can reduce the number of elements for constituting the circuit of the memory system 3, thereby reducing the cost thereof. In FIGS. 1 and 5, only the single transmission line is illustrated, even there is actually a plurality of transmission lines between the memory controller 10 and the memory device 11 and also another plurality of transmission lines between the memory devices 11 and 12. In accordance with the above-described first and second embodiments, each of the transmission lines needs to be terminated by the terminal resistance. In accordance with the third embodiment, the memory system 3 can be free of the terminal resistance for each transmission line. It is advantageous for the memory system 3 that the memory system 3 can be free of the terminal resistance for each transmission line, thereby reducing the number of the necessary elements and also reducing the necessary area for the system 3.

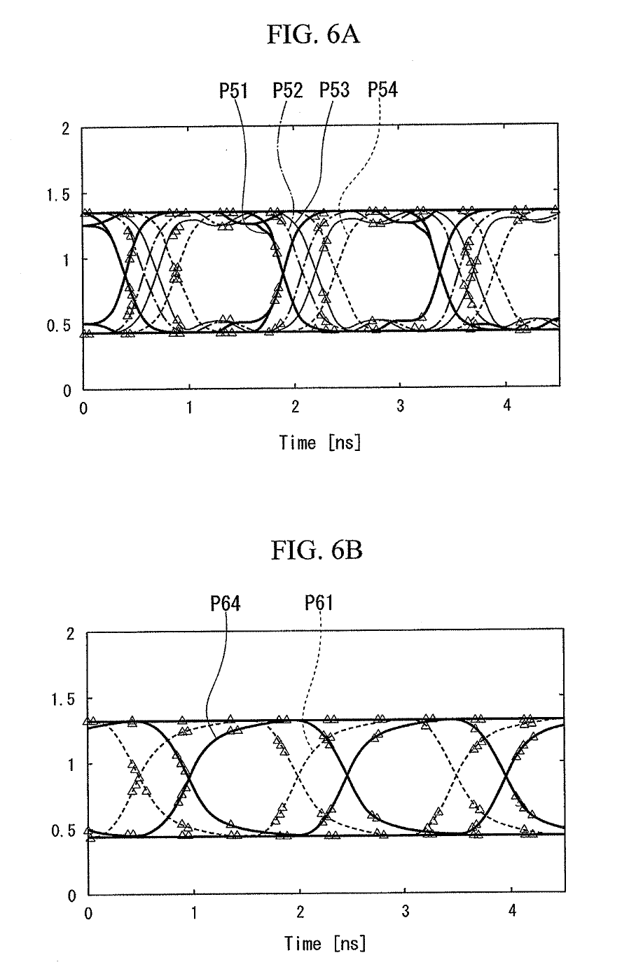

FIG. 6A is a diagram illustrating variation of simulated eye aperture ratio over time in writing operation of the memory modules 21, 22, 31, and 32 of the memory system 3 shown in FIG. 5. FIG. 6B is a diagram illustrating a variation of simulated eye aperture ratio over time in reading operation of the memory modules 21 and 32 of the memory system 3 shown in FIG. 5. The simulation was made under the conditions that a data transfer rate is 666 Mbps at a clock frequency of 333 MHz. These conditions are similar to those shown in FIGS. 4A and 4B.

In FIG. 6A, P51 represents variation of a simulated eye aperture ratio over time for writing data in the memory module 21. P52 represents variation of another simulated eye aperture ratio over time for writing data in the memory module 22. P53 represents variation of still another simulated eye aperture ratio over time for writing data in the memory module 31. P54 represents variation of yet another simulated eye aperture ratio over time for writing data in the memory module 32.

In FIG. 6B, P61 represents variation of a simulated eye aperture ratio over time for reading data out of the memory module 21. P64 represents variation of another simulated eye aperture ratio over time for reading data out of the memory module 32.

FIGS. 6A and 6B show that the simulated eye aperture ratios for writing and reading data to every memory chip are improved as compared to the simulated eye aperture ratios for writing and reading data as shown in FIGS. 10A and 10B.

In accordance with the above descriptions, the memory system 3 is the modification to the memory system 1 of the second embodiment. The modification is made so that the memory device 12 can be free of the chip inductor 35, the transmission line L3 and the terminal resistance 13. The memory system 3 may be the modification to the memory system 1 of the first embodiment. For example, the modification to the memory system 1 of the first embodiment can be made so that there are absent the chip inductor 35, the transmission line L3 and the terminal resistance 13, and instead as shown in FIG. 5 the connecting point between the chip inductor 34 and the capacitor C_{L} is terminated by the Thevenin terminal resistance that includes the series connection of the resistances 32c and 32d. The chip inductor 35, the transmission line L3 and the terminal resistance 13 are absent in the memory system 3 in accordance with the third embodiment, while these elements are present in the above-described memory system 1 in accordance with the first and second embodiments. There are options to modify the memory systems in accordance with the first embodiment and the second embodiment. The inductance of the chip inductor 35 of the second embodiment is smaller than the inductance of the chip inductor 35 of the first embodiment. In one aspect, it might be preferable to modify the memory system of the second embodiment so that the memory device 12 can be free of the hip inductor 35, the transmission line L3 and the terminal resistance 13.

### Fourth Embodiment

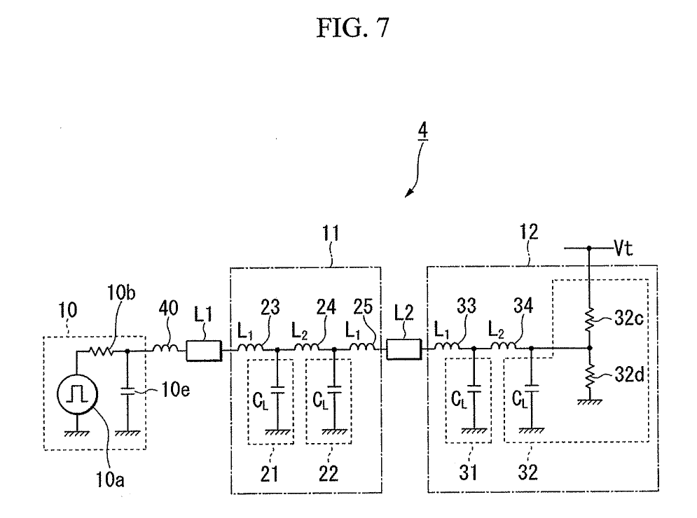

A fourth embodiment of the present invention will be described. FIG. 7 is a diagram illustrating an equivalent circuit of a memory system in accordance with the fourth embodiment of the present invention. The configuration of a memory system 4 in accordance with the fourth embodiment is different from the above-described configuration of the memory system in accordance with the third embodiments. The difference of the fourth embodiment from the third embodiment is the modified configuration of further including an additional chip inductor 40 between the memory controller 10 and the transmission line L1.

As shown in FIG. 7, the memory controller 10 has a parasitic capacitance 10e that is caused by a comparator and a package. In some cases, the parasitic capacitance 10e can be ignorable. In other cases, the parasitic capacitance 10e can not be ignorable because the parasitic capacitance 10e might cause an unintended reflection of signal thereby deteriorating the signal quality. In accordance with the fourth embodiment, the additional chip inductor 40 is disposed between the memory controller 10 and the transmission line L1, so that the additional chip inductor 40 and the parasitic capacitance 10e constitutes a second-order T-low-pass filter that is matched to the characteristic impedance Z₀.

If the characteristic impedance for the transmission lines L1, L2 and L3 is 50 [Ω] and if the parasitic capacitance 10c of the memory controller 10 is 5 [pF] and the above-described cut-off frequency is 900 [MHz] and the second-order T-low-pass filters are Butterworth filters, then the inductance of the chip inductor 40 is 1.25 [nH].

Adjustment or correction to the inductance of the chip inductor 40 can be made. The adjustment or correction to the inductance of the chip inductor 40 is made to countermeasure variation of the parasitic capacitance 10e of the memory controller 10. The adjustment or correction can be made to countermeasure parasitic transistors. The adjustment to the inductance of the chip inductor 40 can be made in the range of about ½ times to about 3 times of the values obtained in accordance with the above-described design method. The correction to the inductance of the chip inductor 40 can be made using a circuit simulator. The adjustment or correction can be made so that the group delay is in the cut-off frequency band and in the range of about ½ times to about 2 times of the averaged value thereof.

In accordance with the fourth embodiment, the additional chip inductor 40 is disposed between the memory controller 10 and the transmission line L1, so that the additional chip inductor 40 and the parasitic capacitance 10e constitutes the second-order T-low-pass filter that is matched to the characteristic impedance Z₀. No unnecessary reflection is caused between the memory controller 10 and the transmission line L1. As a result, no unnecessary reflection is caused throughout the transmission system, thereby preventing deterioration of the signal due to signal reflection. This allows high speed operations of writing and reading data. The design for the memory devices 11 and 12 are basically similar to the design for the low-pass filter. The design for the memory devices 11 and 12 can be made without using any complicated design processes.

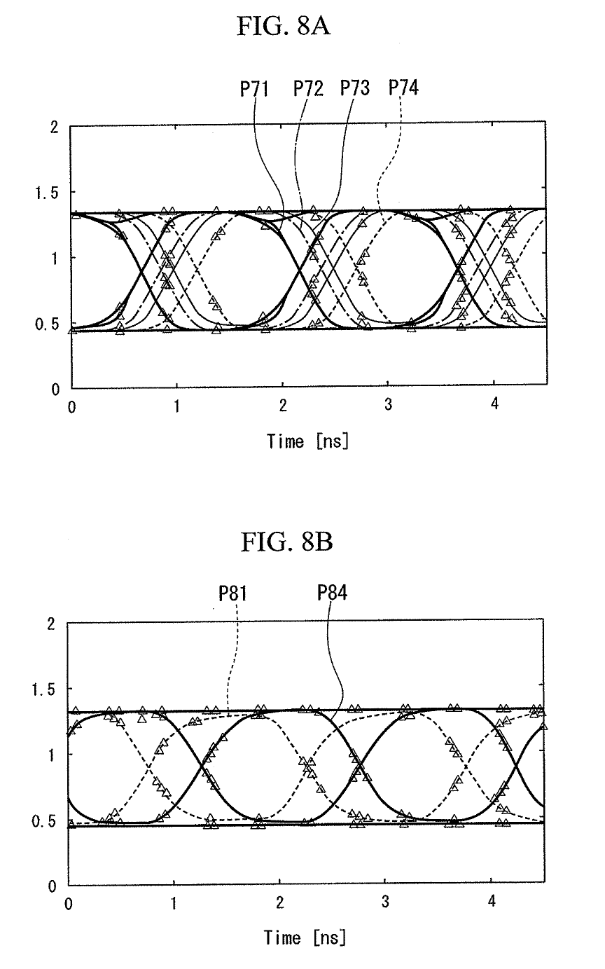

FIG. 8A is a diagram illustrating variation of simulated eye aperture ratio over time in writing operation of the memory modules 21, 22, 31, and 32 of the memory system 4 shown in FIG. 7. FIG. 8B is a diagram illustrating a variation of simulated eye aperture ratio over time in reading operation of the memory modules 21 and 32 of the memory system 4 shown in FIG. 7. The simulation was made under the conditions that a data transfer rate is 666 Mbps at a clock frequency of 333 MHz. These conditions are similar to those shown in FIGS. 6A and 6B.

In FIG. 8A, P71 represents variation of a simulated eye aperture ratio over time for writing data in the memory module 21. P72 represents variation of another simulated eye aperture ratio over time for writing data in the memory module 22. P73 represents variation of still another simulated eye aperture ratio over time for writing data in the memory module 31. P74 represents variation of yet another simulated eye aperture ratio over time for writing data in the memory module 32.

In FIG. 8B, P81 represents variation of a simulated eye aperture ratio over time for reading data out of the memory module 21. P84 represents variation of another simulated eye aperture ratio over time for reading data out of the memory module 32.

FIGS. 8A and 8B show that the simulated eye aperture ratios for writing and reading data to every memory chip are improved as compared to the simulated eye aperture ratios for writing and reading data as shown in FIGS. 10A and 10B.

In accordance with the above descriptions, the memory system 4 is realized by modification to the memory system 3 of the third embodiment, wherein the additional chip inductor 40 is disposed between the memory controller 10 and the transmission line L1, so that the additional chip inductor 40 and the parasitic capacitance 10e constitutes the second-order T-low-pass filter that is matched to the characteristic impedance Z₀.

It is also possible that the memory system 4 of the fourth embodiment can also be realized by modification to the memory system 1 of the first or second embodiment, wherein the additional chip inductor 40 is disposed between the memory controller 10 and the transmission line L1, so that the additional chip inductor 40 and the parasitic capacitance 10e constitutes the second-order T-low-pass filter that is matched to the characteristic impedance Z₀.

### Fifth Embodiment

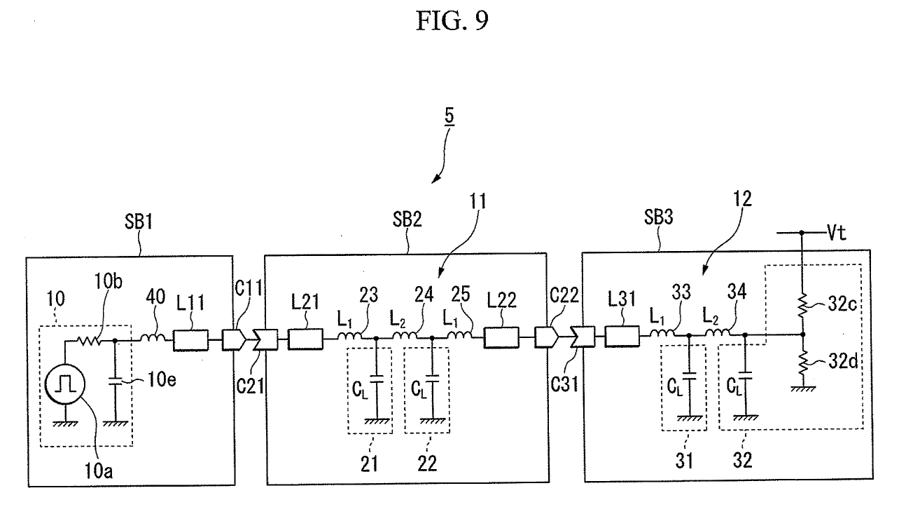

A fifth embodiment of the present invention will be described. FIG. 9 is a diagram illustrating an equivalent circuit of a memory system in accordance with the fifth embodiment of the present invention. The configuration of a memory system 5 in accordance with the fifth embodiment is different from the above-described configuration of the memory system in accordance with the fourth embodiments. The difference of the fifth embodiment from the fourth embodiment is the modified configuration of transmission lines between the memory controller 10 and the memory device 11 and between the memory devices 11 and 12.

As shown in FIG. 9, the memory system 5 includes a first substrate SB1, a second substrate SB2 and a third substrate SB3. The first substrate SB1 has the memory controller 10. The second substrate SB2 has the memory device 11. The third substrate SB3 has the memory device 12. The memory system 5 has a series connection of the first, second and third substrates SB1, SB2 and SB3.

The first substrate SB1 may have not only the memory controller 10 but the additional chip inductor 40, the transmission line L11 and a connector C11. The transmission line 111 has the characteristic impedance Z₀. The transmission line L11 is disposed between the additional chip inductor 40 and the connector C11. The transmission line L11 connects the additional chip inductor 40 to the connector C11.

The second substrate SB2 may have not only the memory device 11 but connectors C21 and C22, and transmission lines L21 and L22. The transmission lines L21 and L22 have the characteristic impedance Z₀. The transmission line L21 is disposed between the connector C21 and the chip inductor 23. The transmission line L21 connects the connector C21 to the chip inductor 23. The transmission line L22 is disposed between the chip inductor 25 and the connector C22. The transmission line L22 connects the chip inductor 25 and the connector C22.

The third substrate SB3 may have not only the memory device 12 but a connector C31 and a transmission line L31. The transmission line L31 is disposed between the connector C31 and the chip inductor 33. The transmission line L31 connects the connector C31 to the chip inductor 33.

The connector C11 of the first substrate SB1 is coupled to the connector C21 of the second substrate SB2 so that the first substrate SB1 is connected in series to the second substrate SB2. The connector C21 of the second substrate SB2 is coupled to the connector C31 of the third substrate SB3 so that the second substrate SB2 is connected in series to the third substrate SB3. Thus, the first, second and third substrates SB1, SB2 and SB3 are connected in series to each other.

In the first substrate SB1, the parasitic capacitance 10e of the memory controller 10 and the additional chip inductor 40 constitute a second-order low-pass filter that is matched to the characteristic impedance Z₀.

In the second substrate SB2, the memory modules 21, and 22 and the chip inductors 23, 24, and 25 constitute a third-order or fifth-order low-pass filter that is matched to the characteristic impedance Z₀.

In the third substrate SB3, the memory modules 31, and 32 and the chip inductors 33 and 34 constitute a third-order or fifth-order low-pass filter that is almost-impedance-matched to the characteristic impedance Z₀.

As a result, no unnecessary reflection is caused throughout the transmission system, thereby preventing deterioration of the signal due to signal reflection. This allows high speed operations of writing and reading data. The design for the memory devices 11 and 12 are basically similar to the design for the low-pass filter. The design for the memory devices 11 and 12 can be made without using any complicated design processes.

In some cases, each of the connectors C11, C21, C22 and C31 may be free of parasitic inductance. In other cases, each of the connectors C11, C21, C22 and C31 may have parasitic inductance. The design for each of the low-pass filters should be made by talking into account the parasitic inductance of each of the low-pass filters, so that the transmission system as a whole constitutes the low-pass filter. When the parasitic capacitance 10e of the memory controller 10 and the additional chip inductor 40 constitute a second-order low-pass filter, the design for the second-order low-pass that is matched to the characteristic impedance Z₀ can be made taking into account that the parasitic inductance of the connector C11 is subtracted from the inductance of the chip inductor C40.

The design for the memory device 11 that is matched to the characteristic impedance Z₀ can be made taking into account that the parasitic inductance of the connector C21 is subtracted from the inductance of the chip inductor 23 as well as the parasitic inductance of the connector C22 is subtracted from the inductance of the chip inductor 25.

The design for the memory device 12 that is matched to the characteristic impedance Z₀ can be made taking into account that the parasitic inductance of the connector C31 is subtracted from the inductance of the chip inductor 33.

It is possible modify the above-described memory device, memory system and design method for the memory device. In the foregoing embodiments, the chip inductors 23, 24, 25, 33, 34, 35, and 40 are used as the lumped constant circuit elements. Namely, the lumped constant circuit elements can be realized by the chip inductors in accordance with the foregoing embodiments. It is possible that the lumped constant circuit elements can be realized by a line inductor that extends from the transmission line. The line inductor includes a non-parallel portion that is not parallel to the transmission line. A typical example of the line inductor may include, but is not limited to, a spiral inductor.

In the foregoing embodiments, the low-pass filter is the T-Butterworth filter. It is possible as modifications that the low-pass filter can be realized by filters, Chebyshev-T-filters, and Chebyshev-π-filters. The π-filters, Chebyshev-T-filters, and Chebyshev-π-filters are in general lower in cut-off frequency as compared to the T-Butterworth filter. The π-filters, Chebyshev-T-filters, and Chebyshev-π-filters are in general effective when the capacitance C_{L} of the memory modules is sufficiently small.

Consequently, the memory system may include, but is not limited to, a transmission line having a characteristic impedance, and at least one low-pass filter coupled to the transmission line, the at least one low-pass filter being matched to the characteristic impedance. The at least one low-pass filter includes a memory device coupled to the transmission line and lumped constant circuit elements placed on the transmission line. Since the at least one low-pass filter is matched to the characteristic impedance of the transmission line, no unnecessary signal-reflection is caused throughout the transmission system, thereby preventing deterioration of the signal due to signal reflection. This allows high speed operations of writing and reading data. The design for the memory devices 11 and 12 are basically similar to the design for the low-pass filter. The design for the memory devices 11 and 12 can be made without using any complicated design processes.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A memory device comprising:
at least one memory module electrically coupled to a transmission system that has a characteristic impedance; and
a plurality of lumped constant circuit elements with an inductance being placed on the transmission system symmetrically with reference to the at least one memory module, the plurality of lumped constant circuit elements in cooperation with the at least one memory module performing as at least one low-pass filter.

2. The memory device according to claim 1, wherein the at least one low-pass filter has a cut-off frequency that is higher than a clock frequency of a clock signal that is used to transmit a signal on the transmission system.

3. The memory device according to claim 1, wherein the at least one low-pass filter is matched to the characteristic impedance.

4. The memory device according to claim 1, wherein each of the plurality of lumped constant circuit elements comprises a chip inductor.

5. The memory device according to claim 1, wherein each of the plurality of lumped constant circuit elements comprises a line inductor that extends from the transmission system, the line inductor comprises a non-parallel portion that is not parallel to the transmission system.

6. The memory device according to claim 1, wherein the at least one memory module comprises a plurality of memory modules electrically coupled to a plurality of transmission lines included in the transmission system, and
the plurality of lumped constant circuit elements in cooperation with the plurality of memory modules performing as the third-order or fifth-order low-pass filter.

7. A memory system comprising:
a transmission system that includes a plurality of transmission lines that each have a characteristic impedance;
a plurality of memory modules electrically coupled to the transmission system;
a plurality of lumped constant circuit elements with an inductance being placed on the transmission system symmetrically with reference to the plurality of memory modules, the plurality of lumped constant circuit elements in cooperation with the the plurality of memory modules performing as at least one low-pass filter; and
a memory controller electrically coupled to the transmission system, the memory controller controlling operations of writing information into the plurality of memory modules and reading information out of the plurality of memory modules.

8. The memory system according to claim 7, further comprising:
at least one additional lumped constant circuit element with an inductance being placed on the transmission system, the at least one additional lumped constant circuit element in cooperation with the memory controller performing as an additional low-pass filter.

9. The memory system according to claim 7, wherein the at least one low-pass filter has a cut-off frequency that is higher than a clock frequency of a clock signal that is used to transmit a signal on the transmission system.

10. The memory system according to claim 7, wherein the at least one low-pass filter is matched to the characteristic impedance.

11. The memory system according to claim 7, wherein each of the plurality of lumped constant circuit elements comprises a chip inductor.

12. The memory system according to claim 7, wherein each of the plurality of lumped constant circuit elements comprises a line inductor that extends from the transmission system, the line inductor comprises a non-parallel portion that is not parallel to the transmission system.

13. The memory system according to claim 7, wherein the at least one low-pass filter performs as the third-order or fifth-order low-pass filter.

14. A method of design for a memory device, the method comprising:
placing a plurality of lumped constant circuit elements with an inductance on a transmission system that has a characteristic impedance that is electrically coupled to at least one memory module, so that the plurality of lumped constant circuit elements is symmetrical with reference to the at least one memory module; and
deciding the inductance of the plurality of lumped constant circuit elements, so that the plurality of lumped constant circuit elements in cooperation with the at least one memory module performs as at least one low-pass filter.

15. The method according to claim 14, wherein the at least one low-pass filter has a cut-off frequency that is higher than a clock frequency of a clock signal that is used to transmit a signal on the transmission system.

16. The method according to claim 14, wherein the at least one low-pass filter is matched to the characteristic impedance.
